(19) United States
(12) Patent Application Publication
(10) Pub. No.: US 2026/0350261 A1
(43) Pub. Date: Nov. 5, 2026

(54) ARTIFICIAL INTELLIGENCE METHOD FOR DESIGNING THE LIGHTEST PRE- ENGINEERED STEEL BUILDING

(71) Applicant: Mehmet KAPAR, URLA, IZMIR (TR)

(72) Inventor: MEHMET KAPAR, Urla (TR)

(21) Appl. No.: 19/182,144

(22) Filed: Apr. 17, 2025

(51) Int. Cl. G06F 30/20; G06F 30/13

(52) U.S. Cl. CPC G06F 30/20; G06F 30/13

(57) ABSTRACT

A computer-implemented method is provided for identifying primary-member cross-sections for pre-engineered steel buildings that yield material-efficient, code-compliant, and practically constructible designs within a short time. Possible design scenarios subject to cross-section limitations based on AISC 360, AISC 341, and practical constructability limitations derived from industry practice can be generated. Using a rule-based system trained on 10,000 pre-engineered steel building designs having different geometric and loading configurations, loaded in accordance with ASCE 7 and IBC 2024, and designed in accordance with AISC 360 and AISC 341, optimum ranges of cross-section dimensions can be determined based on building type, building dimensions, and applied loading, which significantly narrows the search space. An enhanced search algorithm can be applied that identifies promising scenarios by wide-field scanning and performs narrow-field deep scanning around the promising scenarios.

### BACKGROUND OF THE INVENTION

### Field of the Invention

The present invention relates generally to the design of pre-engineered steel buildings, and in particular, to a method and computer program product for optimal design of the pre-engineered steel buildings.

### Description of the Related Art

(Note: This application references a number of different publications as indicated throughout the specification by a name and year enclosed in brackets, e.g., [Rajeev 1997]. A list of these different publications ordered according to these names and years can be found below in the section entitled “REFERENCES”. Each of these publications is incorporated by reference herein.)

### Pre-Engineered Steel Buildings (PEBs)

The use of steel structures in industrial buildings is rapidly growing across the globe [Sagavekar 2021]. The industrial buildings can be classified based on their design concepts as Conventional Steel Buildings (CSB) and Pre-Engineered Steel Buildings (PEB) [Balamuralikrishnan 2019]. In CSB, standard hot-rolled I or C cross-sections are employed, which may be significantly heavier in many parts than what is required by design. These cross-sections have standard dimensions that cannot be modified based on the requirements [Maria Subashini 2015]. The PEB concept is based on varying cross-section sizes along the height of the structure to meet the specific requirements at each point, as determined by the bending moment diagram. This is achieved by attaching built-up thin plates, with varying lengths, to the I-cross-section [Rao 2014].

PEB structures mainly consist of primary structural members (columns and rafters), secondary structural members (purlins, girts, and bracings), and sheeting/cladding (panels for roof and walls) [Sunanda 2022]. PEB structures are used for different types of buildings such as industrial buildings, warehouses, workshops, commercial complexes, corporate office buildings, indoor stadiums, outdoor stadiums with canopies, fuel stations, metro stations, bus terminals, parking lots, large exhibition centers, aircraft hangers, labor camps, community centers, railway stations, and railway storage yards [Milan Girishkumar 2022].

Studies have demonstrated that PEB outperforms CSB in several aspects, including steel usage [Gilbile 2020]. Therefore, the use of PEB systems has increased dramatically in recent years. In a project, the reduction in steel usage not only lowers material costs but also reduces labor, shipping, and erection expenses. Additionally, since steel production is a major source of carbon dioxide emissions, using less steel helps decrease these emissions, making PEB systems more environmentally friendly.

In addition to the use of PEB systems, designing these systems optimally is crucial for further reducing steel usage.

In the traditional PEB design process, the initial cross-section dimensions are usually chosen based on the designer's experience and knowledge of similar structures. These initial cross-sections are then utilized to model the structure in analysis and design software. Next, the loads operating on the structure, such as dead, live, wind, snow, and seismic loads, are computed and applied to corresponding components. The software then analyzes the structure to calculate internal forces, moments, and displacements. Based on the results, structural components are evaluated for compliance with design regulations and safety requirements such as strength, stability, and serviceability. If any cross-sections are discovered to be insufficient, their sizes are incrementally modified until all members satisfy the design standards. This method is repeated until a code-compliant design is obtained ([Lee 2015]; [Syed Shujat 2018]).

However, the process is time-consuming, and for a structural designer, it takes an average of 5 hours to model a structure, and calculate the loads applied to each primary member, and for finding a solution, it typically takes an average of 15 minutes to assign members, perform a structural analysis, check the results, and conduct a cost analysis.

FIG. 1 shows a sample PEB model 100. As can be seen in this figure, for the presented model, there are 7 design variables (side columns 102, middle columns 104, rafters 106, Dₓ 108, D_{y} 110, Dₘ 112, and Dᵣ 114). Assuming there are 6000 options for each side column 102, middle column 104, and rafter 106, and there are 5 options for each Dₓ 108, D_{y} 110, Dₘ 112, and Dᵣ 114, in total, there are 6,000 (Side column 102)×6,000 (middle column 104)×6,000 (rafter 106)×5 (Dₓ 108)×5 (D_{y} 110)×5 (Dₘ 112)×5 (Dᵣ 114)=1.35×10¹⁴ (135 trillion) scenarios 134. Therefore, it is impossible for a structural designer to evaluate all these scenarios manually to identify the most optimal solution.

Furthermore, the optimal values of the design variables 136 vary significantly depending on the type of PEB model (e.g., single-span, multi-span, mono-slope, multi-gable), the structural properties (e.g., presence of mid-columns, type of base support—fixed or pinned, type of side columns—straight or tapered), and the loading properties (e.g., snow load, wind load, crane load). Therefore, there may be more than one thousand different conditions in total. As a result, it is unrealistic for a structural designer to have experience in designing for all these conditions or to fully understand the appropriate optimal range of each design variable 136 for each condition. Consequently, the designer's selected values for design variables 136 may be insufficient or adequate but still significantly deviate from the optimal ranges.

Together, these issues—requiring significant time for each analysis, the existence of numerous scenarios 134, and the inability to have experience in designing all models and load conditions—make it nearly impossible for a structural designer to reach the optimum solution. Therefore, in recent years, novel methodologies for PEB structure design have been proposed [Babaei 2022].

### Metaheuristic-Based Optimization of PEB

[Kaveh 2019] used nine metaheuristic algorithms for geometry and sizing optimization of steel-pitched roof frames with tapered members. These algorithms consist of simulated annealing optimization, particle swarm optimization, artificial bee colony, whale optimization algorithm, grey wolf optimizer, invasive weed optimization, harmony search, colliding bodies optimization, and enhanced colliding bodies optimization algorithms. The objective function of their optimization problem was taken as minimizing the total weight of the primary members of structures. The design variables considered in their optimization problem were the width 124 and thickness 126 of the flange and the height 128 and thickness 132 of the web of column, rafter, and ridge cross-sections. Some variables are related to each other, for instance, the top part of the column must be larger than the bottom part. Therefore, they defined some limitations for the height of the cross-sections as follows: the height of the cross-section at the top of the columns must be greater than the heights of cross-sections at the bottom of columns and the rafters, and the height of the cross-section in the ridge cross-section must be greater than the height of rafter cross-sections. Moreover, in their optimization, to prevent the optimization algorithms from generating impractical cross-sections 122, the flange width 124 was fixed, the flange thickness 126 was restricted to one of two predetermined values, the web thickness 132 was kept constant, and the web height 128 was limited to one of nine specified values. The performance of the algorithms in reaching the optimum values is evaluated and compared with the real optimum values reached by general search in the determined limited variables boundaries. According to their results, the solutions found by the algorithms lead to just 1% to 6% heavier solutions compared to the minimum cost found by the general search technique. However, in the proposed optimal design method, the flange width 124 and web thickness 132 are assumed to be constant. Moreover, limited options for sizes of the flange thickness 126 and web height 128 were defined in the study. This approach significantly reduces the likelihood of finding truly optimal solutions.

[Kaveh 2019] used five meta-heuristic algorithms for the optimal design of multi-span pitched roof frames with tapered members. They used teaching-learning-based optimization, colliding bodies optimization, enhanced colliding bodies optimization, and vibrating particle system algorithms for the optimization. In addition to the web height 128, web thickness 132, flange width 124, and flange thickness 126 of the column, rafter, and ridge cross-sections, the tapered length ratio was considered in their optimization. The flange width 124 and thickness 126 were assumed to be constant values, and the web height 128 range was limited to one of nine determined sizes regarding the flange width 124 size to reach a practical cross-section size. The web thickness 132 size is also limited to one of three predefined values. Tapered length ratio is limited to one of nine determined values within a range from 10% to 45%. According to their results, all the algorithms were able to achieve nearly identical optimal solutions. Additionally, they concluded that a 15% change in the roof angle could lead to a 10% variation in the weight of the structures. Furthermore, their findings indicated that an increase in the apex height results in an increase in the optimal weight of the structures. In this study, similar to ([Kaveh 2019]; [Arzani) 2019]) several design variables 136 are kept constant or limited to prevent the optimization algorithm from considering impractical cross-sections. However, the constraints and limitations dramatically diminish the chances of finding the globally optimal solution among all feasible scenarios.

[Kaveh 2021] applied four population-based metaheuristic optimization algorithms to the optimal design of portal frames. These algorithms consist of teaching-learning-based optimization, enhanced colliding bodies optimization, shuffled shepherd optimization algorithm, and water strider algorithm. The objective function of the optimization problem was assumed to be minimizing the total weight of the frame structures subjected to the following design constraints: stability constraints, buckling constraints, strength constraints, maximum vertical displacement, and maximum horizontal displacement. SAP2000 was utilized in their study to assess the structural model and to gather the data needed to evaluate the design constraints. They used the open application programming interface to integrate SAP2000 with MATLAB. The design variables in the optimization problem were flange width 124, flange thickness 126, web height 128, and web thickness 132 for each cross-section of the frame structure. In one research example, they determined 7 potential flange thickness 126 and web thickness 132, 51 web heights 128, and 31 flange widths 124. The optimization algorithms found similar best solutions within the specified range of variables. However, since the optimization algorithm independently optimizes each design variable 136 (thickness, height, and width of the cross-sections), the cross-sections 122 proposed by the algorithms may be impractical for real-world applications. Additionally, due to the independent optimization of cross-sections 122, assembling the cross-sections 122 proposed by algorithms in a structure may not be feasible to construct or appropriate either architecturally or economically.

[Salama 2023] used a metaheuristic algorithm, the enhanced crystal structure algorithm (ECryStAl), for the optimal design of steel gable frames with tapered members. The function of this algorithm was compared with seven metaheuristic algorithms including CryStAl, grey wolf optimizer, enhanced colliding bodies optimization, genetic algorithm, fusion-fission optimization, mycorrhiza tree optimization algorithm, and transit search. According to the comparison the ECryStAl managed to outperform the other algorithms by reaching a solution with lower weight. The number of design variables in their optimization equals 10. However, similar to other mentioned works, in this optimization method, the design variables 136 are optimized independently. For this reason, their proposed methodology found a solution that the flange width 124 of the side column 102 is smaller than the flange width 124 of the rafter 106, which is undesirable and almost impractical.

As mentioned above, the proposed methods independently optimize each design variable 136 including flange width 124, web height 128, flange thickness 126, web thickness 132 of cross-sections 122 of columns 102, 104 and rafters 106 as well as Dₓ 108, D_{y} 110, Dₘ 112, and Dᵣ 114. Therefore, the algorithms may find a cross-section 122 that the sizes of its flange width 124, web height 128, flange thickness 126, web thickness 132 are not compatible with each other. Secondly, algorithms may find a cross-section as an optimal solution because it is lighter than other options while its preparation may lead to waste of more steel plates during the fabrication process. As a result, in total, even though the found optimum cross-section 122 itself may need less steel compared to other options, preparation of such a cross-section 122 may need more steel plate. Thirdly, since the algorithms independently optimize each design variable 136 the solution found by the algorithm may not be possible or desirable in terms of construction. For example, it may find a solution such that the flange width 124 of the rafter 106 is larger than the flange width 124 of its relying column 102. Fourthly, a few of the methods have extremely limited or fixed range of certain design variables 136 to avoid finding infeasible and undesirable solution issues, but this limitation and fixing strategy excludes numerous potential scenarios from being considered in the optimization process, while each of these numerous excluded scenarios may offer more optimal solutions.

Therefore, the solution is to have a methodology that:
suggests solutions that consist of cross-sections 122 that their parts are compatible with each other.
suggests solutions that their construction is possible or desirable.
considers minimizing the steel usage during the fabrication process.
considers numerous options to find the best solution.
requires a reasonable time to find the optimum solution.

### SUMMARY OF THE INVENTION

In summary, the invention provides a computer-implemented algorithm for the optimal design of PEB structures. Users can define structural and loading properties, such as span length, column height, snow, seismic, and wind parameters. Using a trained model and various constraints, the algorithm generates and systematically searches and evaluates multiple design scenarios, automatically calculating loads, performing structural analysis, checking regulatory compliance, and conducting cost analysis to identify the most optimal solution within a short timeframe. A numerical study demonstrated that, while the weight of the primary members of the structure could vary from 63 to over 134 tons, the algorithm consistently found designs in the 63-66 ton range with a probability of less than 0.1% in the state space. The entire optimization process took less than 30 minutes, compared to traditional design methods, which may take a full week to achieve comparable results. This invention not only benefits companies and investors by reducing designing time, and project costs, but also helps protect ecosystems and combat climate change by reducing CO2 emissions.

### BRIEF DESCRIPTION OF THE DRAWINGS

Referring now to the drawings in which like reference numbers represent corresponding parts throughout:

FIG. 1 illustrates design variables for a sample PEB structure, and sample values for them;

FIG. 2 illustrates the methodology of the hill climbing algorithm for finding the maximum point in a state space;

FIG. 3 illustrates the methodology of the hill climbing with random restart algorithm for finding the maximum point in a state space;

FIGS. 4A and 4B illustrate the first phase (wide field scanning) and second phase (narrow field deep scanning) methodology of the random restart with selective hill climbing algorithm for finding the maximum point in a state space;

FIG. 5 presents descriptions of design variables for different PEB types;

FIG. 6 presents the flowchart of the first part of the proposed method, appropriate scenarios creation;

FIG. 7 presents the flowchart of the second part of the proposed method, wide field scanning;

FIG. 8 presents the flowchart of the third part of the proposed method, narrow field deep scanning;

FIG. 9 illustrates a 3D model of the PEB structure used in the numerical example;

FIG. 10 shows how the algorithm searches the state space to find promising regions and optimum scenarios;

FIG. 11 illustrates the distribution of the passed solutions' weight in the state space in the numerical example;

FIG. 12 illustrates the distribution density of the total weight of the primary members of solutions for each run of optimization in the numerical example;

FIG. 13 illustrates the distribution density of the total cost of the primary members of solutions for each run of optimization in the numerical example; and

FIG. 14 illustrates the distribution density of the total weight per meter square for the primary members of solutions for each run of optimization in the numerical example.

### DETAILED DESCRIPTION OF THE PREFERRED EMBODIMENTS

### Overview

Embodiments of the invention provide a computer-implemented algorithm to automate the optimal design process of PEB structures 100. A typical PEB structural design process involves modeling the structure in structural analysis software, manually calculating loads on each structural member, applying the loads, performing structural analysis, checking regulatory compliance, and conducting cost analysis. The initial process can take several hours, including load calculations (seismic, wind, snow, crane, etc.), while subsequent iterations—modeling, analysis, compliance checks, and cost evaluation—may take tens of minutes per round. However, a significant percentage of the attempted models may result in undesired capacity ratios or structural responses. As a result, after a full day of work, a structural designer may find only a few solutions, ultimately selecting the lightest one as the final design.

In embodiments of the invention, the structural properties of the PEB 100 are defined by the user, and the algorithm automatically creates all appropriate scenarios. It then systematically explores a wide range of appropriate scenarios, automatically calculating and applying loads, performing structural analysis, checking regulatory constraints, and conducting cost analysis for each case. Subsequently, the algorithm performs a narrow field deep scanning around promising solutions to identify the most optimal design. However, the entire process takes less than one hour on a standard computer. The results of multiple runs of the algorithm in a numerical example showed that the obtained solutions had only slight cost variations, demonstrating the algorithm's success in finding optimal solutions in a few minutes.

### Formulation

Random Restart with Selective Hill Climbing Algorithm

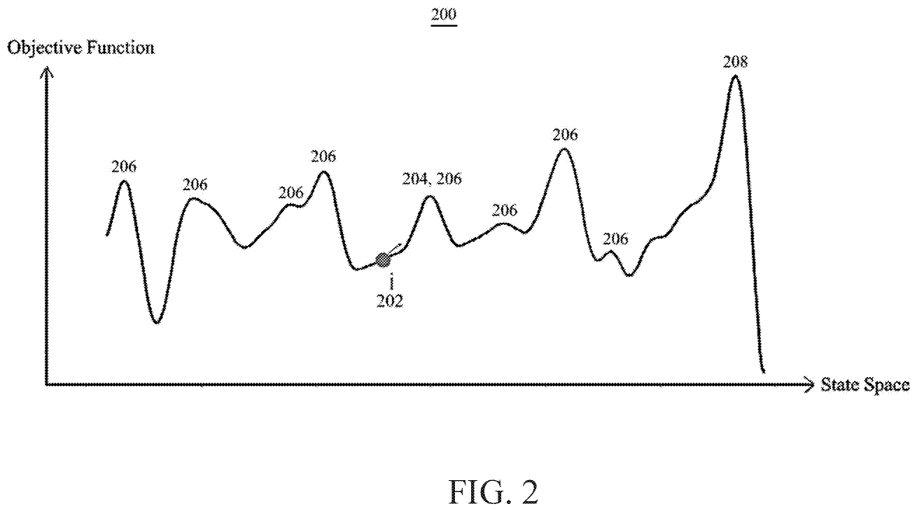

The Hill Climbing (HC) algorithm is a prominent optimization strategy in Artificial Intelligence (AI) for determining the most effective solution to a given problem [Pappala 2023]. It works as a local search algorithm, so it iteratively refines an existing solution and assesses if each change leads to improvement. This strategy is similar to the process of climbing a hill, where the aim is to constantly improve the position until reaching the top, or a local optimum, beyond which no rise is possible. HC algorithm is used in many studies ([Liu 2018]; [Dordaie 2018]; [Lim 2006]). FIG. 2 shows the HC algorithm strategy 200, movement of a state (solution i 202) toward the neighbor hill 204. The algorithm starts with an initial solution, i 202, which is selected at random. Then, by making little modifications or alterations, it looks at the options that are close to the existing ones. It switches to one of these nearby options if any of them are preferable according to a predetermined assessment criterion. Iteratively, this method is carried out until no superior surrounding solution is discovered [Sathiyaraj 2022].

As shown in FIG. 2, there are multiple hills (local maxima) 206, and solutions often converge to a local maximum 206, which may not represent the global maxima 208. To address this limitation, the random restart hill climbing algorithm was introduced [Russell 2002]. The RRHC algorithm is a meta-heuristic optimization algorithm [Escamilla-Serna 2022] that has been employed in numerous studies ([Kato 2018]; [Qin 2019]; [Caldeira 2019]).

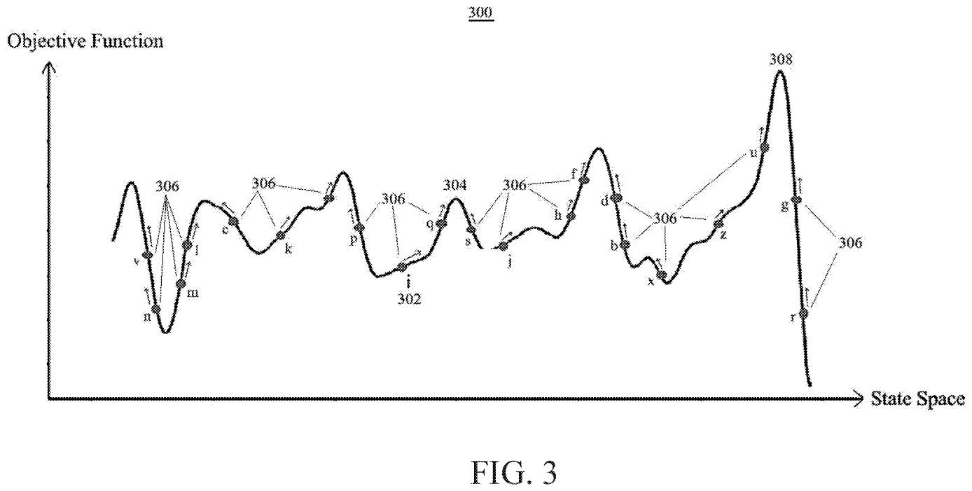

FIG. 3 illustrates the functioning of this algorithm. This approach begins similarly to the standard Hill Climbing algorithm by identifying a local maximum 304 around an initial point (solution i 302). After reaching this point, by a random restart, the algorithm selects a new starting solution 306, and the local optima 306 around that solution is then found. This process of restarting and finding a local optima 306 continues until a predefined number of restarts is completed or until the stop criteria are met or until a predetermined number of iterations have passed with no improvements [Tran 2022]. This method increases the possibility of reaching the global maxima 308 [Selvam 2019]. Random restart hill climbing improves the chances of finding the global maxima 308 but can be impractical for certain applications due to the significant time needed for restarts and local research.

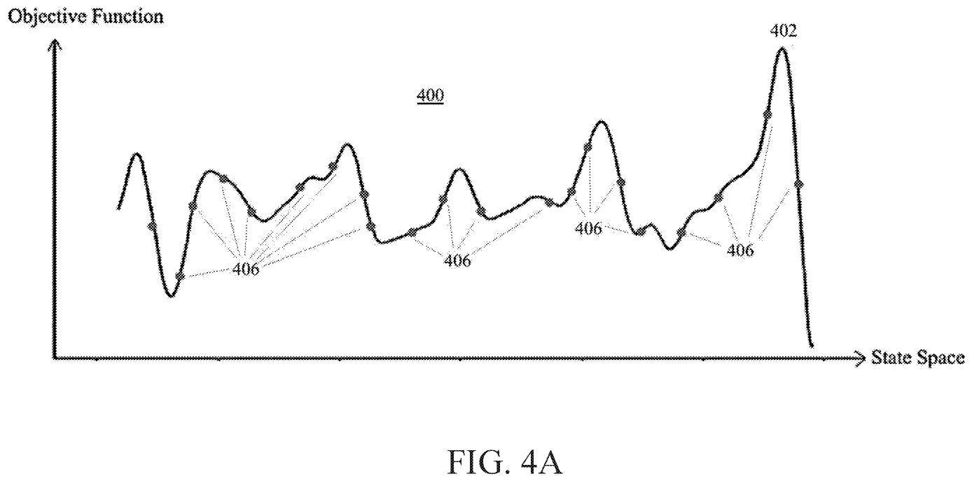

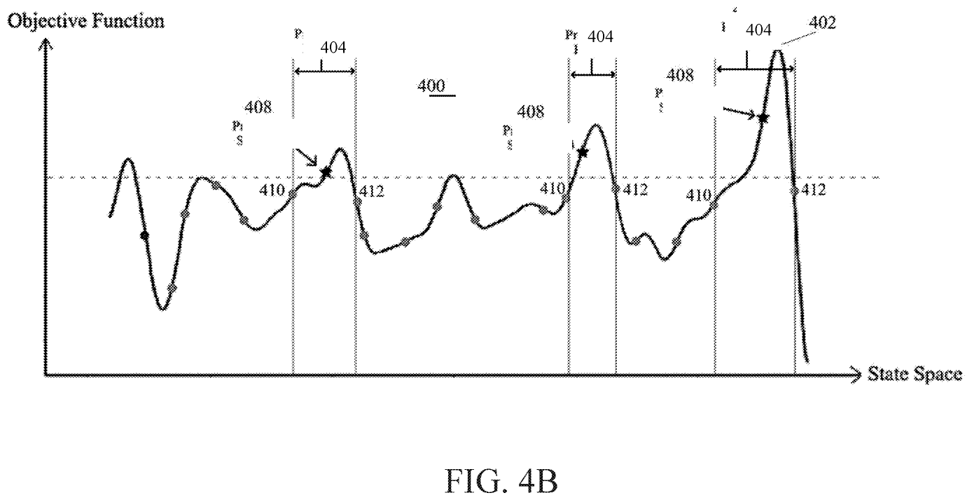

Although the random restart hill climbing algorithm increases the likelihood of reaching the global maxima 308, the multiple restarts and climbing to find local optima 304 in each restart can make the approach time-consuming and impractical for certain applications. Therefore, inspired by this method, a new method, Random Restart with Selective Hill Climbing (RRSHC) algorithm, is designed. FIGS. 4A and 4B illustrate the functioning of the RRSHC algorithm.

As shown in FIGS. 4A and 4B, this method decouples the exploration and exploitation phases, leveraging random restarts to identify promising regions in search space 400 and applying hill climbing to find the most optimum solution 402 within the promising regions 404. By focusing computational resources on promising regions 404, the algorithm balances global search capabilities with local optimization precision.

Phase 1: Exploration via Random Restarts (Wide Field Scanning): The algorithm starts by randomly selecting a user-defined number of points 406 in the search space 400 and evaluating their corresponding costs. Next, based on the cost of the evaluated points 406, promising points 408 and regions 406 are identified. In contrast to the HCRR algorithm, which combines exploration and exploitation in every iteration, the proposed method first explores all randomly selected points 406 during an exploration phase before focusing on exploitation.

Phase 2: Selective Exploitation through Hill Climbing (Narrow Field Deep Scanning): In this phase, hill climbing is applied exclusively to the promising points 408. For each such point, a local search is conducted within its promising region 404 to find a more optimum solution. By focusing just on a few promising regions 404, the algorithm reduces redundant computations and ensures that the exploitation phase is targeted and efficient.

In FIG. 4B, the promising regions 404 are shaded, extending from the previous point 410 to the next point 412 of each of the three most optimal solutions 408 found in first-round optimization.

### Optimal Design of PEB Structures Using RRSHC Algorithm

### Objective Function and Variables

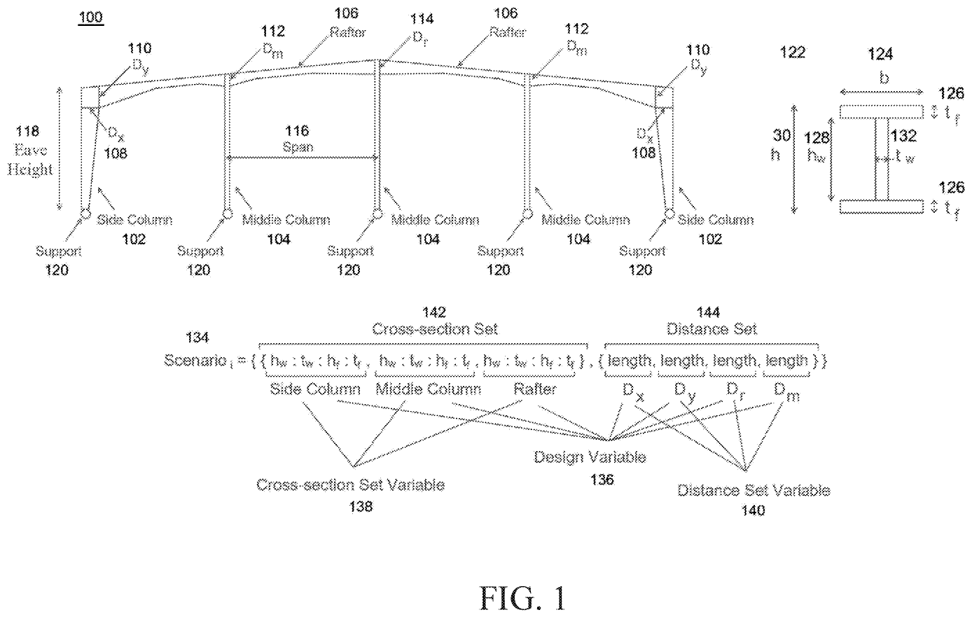

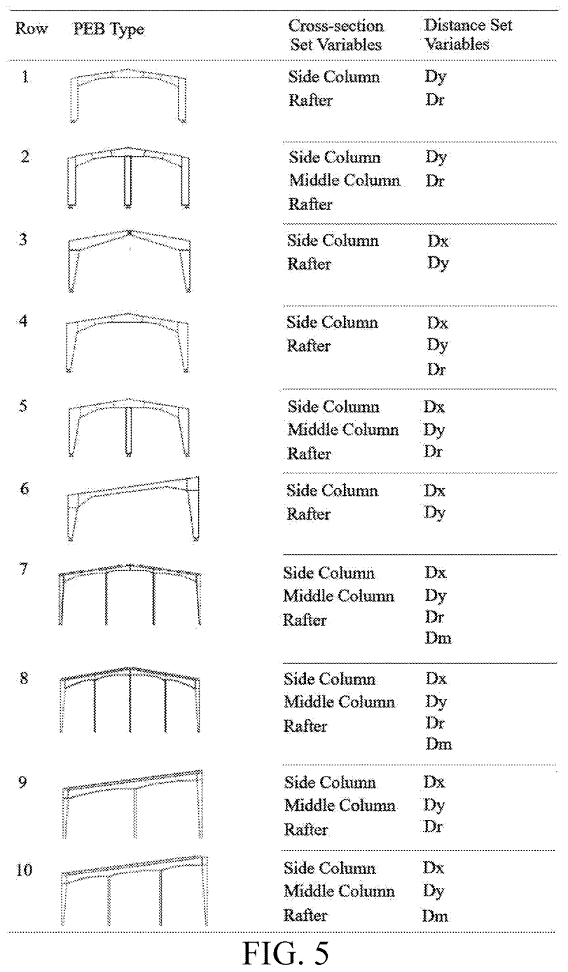

The objective function is defined as minimizing the total weight of primary members. The variables of optimization are cross-sections 122 of rafter 106 and columns 102 104 (Cross-section set variables 138), and the lengths of Dₓ 108, D_{y} 110, Dₘ 112, and Dᵣ 114 (Distance set variables 140). FIG. 1 illustrates these design variables 136 for a sample PEB structure 100. FIG. 5 presents descriptions of design variables for different PEB types.

### Optimization Steps

The proposed methodology comprises four parts: cross-section with smart dimensions creation 602, appropriate scenarios creation 600, wide field scanning 700, and deep scanning of promising narrow field 800. A detailed description of each of the four parts is provided in the following sections.

Creating Cross-Section with Smart Dimensions 602

Almost all the proposed methodologies in the literature define the objective function of their optimal design as minimizing the weight of steel used in the cross-sections of structures. However, from a broader perspective, steel usage is not limited to the steel used in the structural cross-sections 122 but also includes the steel consumed during the manufacturing of these cross-sections 122, encompassing both utilized and wasted portions. For instance, producing four pieces, each with a width of 0.35 meters, from a plate with a width of 1.5 meters results in wasting 0.1 meters of the plate's width. Therefore, as an example, although a cost analysis of a steel project based on the weight of the structure's elements indicates a requirement of 70 tons of steel, in reality, 80 tons of steel plates should be used to produce the 70 tons of steel elements. Therefore, for both cost-saving and carbon dioxide emission considerations, reducing steel usage during the manufacturing process is essential—not just focusing on reducing the weight of the cross-sections. For this reason, in this methodology, considering the width of globally available steel plates, sets of appropriate flange width 124, and web height 128 are prepared. The sets are presented as follows:
Flange width 124, b (mm)={126, 125, 140, 150, 134, 140, 172, 180, 200, 250, 300}
Web height 128, h (mm)={200, 250, 300, 333, 400, 500, 600, 750, 800, 900, 1000}

Afterward, using a set of items for flange thickness 126 and a set of items for web thickness 132, both presented in the following, all combinations of the flange width 124, web height 128, flange thickness 126, and web thickness 132 are provided as cross-sections 122 with smart dimensions.
Flange thickness 126, t_{f} (mm)={8, 10, 12, 14, 15, 16, 20, 25, 30}
Web thickness 132, t_{w} (mm)={8, 10, 12, 14, 15, 16, 20, 25, 30}

### Appropriate Scenarios Creation 600

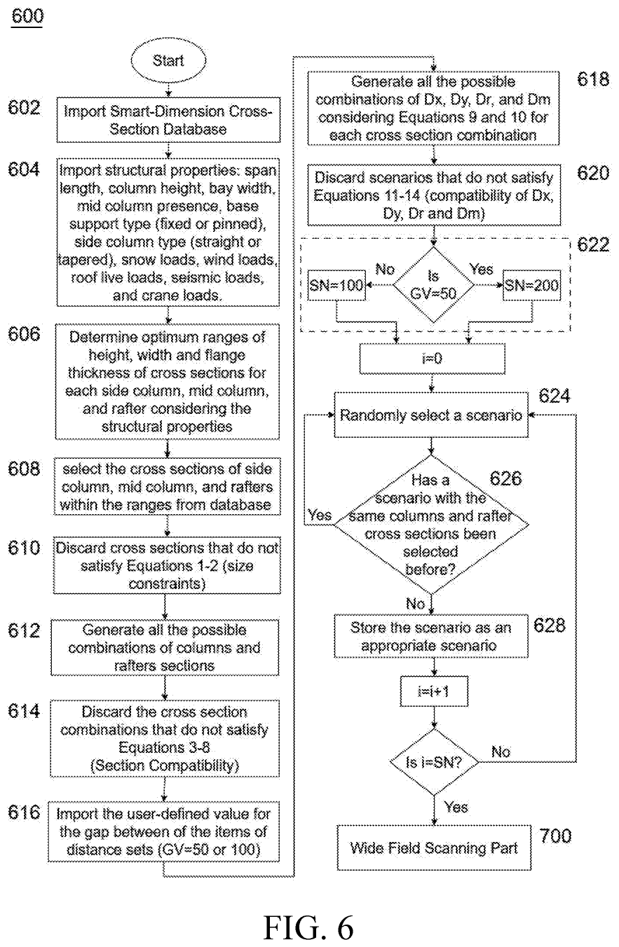

As mentioned earlier, the previously proposed optimization independently finds the optimum value for each design variable 136 including cross-sections 122 of columns 102 104, and rafter 106, as well as Dₓ 108, D_{y} 110, Dₘ 112, and Dᵣ 114. Therefore, the solutions provided by these methods may be unconstructive or economically and architecturally inappropriate. In this method, following the below steps, the inappropriate scenarios are discarded. FIG. 6 presents the flowchart of the appropriate scenarios creation part 600.

In this part, first a database including built-up H cross-section 122 with smart dimensions is provided 602. Then, the structural properties such as span length 116, eave height 118, bay width, mid-column 104 presence, base support 120 type (fixed or pinned), side-column 102 type (straight or tapered), snow loads, and wind loads are imported 604.

Then considering the imported structural properties, by using a trained model, the appropriate ranges of web height 128 and web thickness 132, and flange width 124, and flange thickness 126 of cross-sections 122 for each side column 102, mid-column 104, and rafter 106 are found 606. Afterwards, within the ranges, the algorithm selects the cross-sections 122 of the side column 102, mid-column 104, and rafters 106 from the database 608.

Next, cross-sections 122 that do not satisfy size constraints (Equations 1-2) are discarded 610.

b≤18t_{f} (1)

0.5t_{f}≤t_{w}≤t_{f} (2)

where, b, t_{f}, and t_{w} are flange width 124, flange thickness 126, and web thicknesses 132, respectively.

By using the selected cross-sections all the possible combinations of cross-sections 122 of the columns 102 104 and rafter 106 are generated 612.

Then, the cross-section 122 combinations that do not satisfy cross-section compatibility constraints (Equations 3-8) are discarded 614.

h_{rafter}≤h_{sc} (3)

b_{rafter}≤b_{sc} (4)

b_{MC}≤b_{sc} (5)

h_{MC}≤h_{sc} (6)

b_{rafter}=b_{MC} (7)

t_{f}_{_{MC}}≤t_{f}_{_{SC}} (8)

where, h_{sc}, h_{MC}, and h_{rafter} are web heights 128 of side columns 102, middle columns 104, and rafters 106, respectively. Moreover, b_{sc}, b_{MC}, and b_{rafter} are flange widths 124 of side columns 102, middle columns 104, and rafters 106, respectively. In Equation 8, t_{f}_{_{MC}}, and t_{f}_{_{SC}} indicate the flange thickness 126 of middle columns 104 and side columns 102, respectively.

Next, the gap between the values of the items in each distance set variables 140 are imported 616. The gap between the items can be 50 mm or 100 mm determined by users, both types of distance set 144 are presented in the following:
50-mm gap: Dₓ=D_{y}=Dᵣ=Dₘ (mm)={400, 450, 500, 550, 600, 650, 700, 750, 800, 850, 900, 950, 1000, 1050, 1100, 1150, 1260, 1250, 1320, 1350, 1400, 1450, 1500}
100-mm gap: Dₓ=D_{y}=Dᵣ=Dₘ (mm)={400, 500, 600, 700, 800, 900, 1000, 1100, 1260, 1320, 1400, 1500}

Afterward, considering the limits of Dₓ 108, D_{y} 110, Dₘ 112, and Dᵣ 114, (Equations 9-10), and the distance set 144 type (50-mm gap or 100-mm gap), all possible combinations of Dₓ 108, D_{y} 110, Dₘ 112, and Dᵣ 114 are generated 618.

$$min D = max \{ \begin{matrix}400 mm \\ 1.8 {h}_{SC}\end{matrix} \} \qquad ( 9 )$$

$$max D = min \{ \begin{matrix}7. {b}_{SC} \\ X {h}_{SC} \\ min \{ \begin{matrix}260 mm \\ 0.4 \frac{{E}_{s}}{{E}_{y}}\end{matrix} \} * {t}_{{f}_{SC}}\end{matrix} \} \qquad ( 10 )$$

In Equation 9, h_{sc} is the web height 128 of side columns 102. In Equation 10, E_{S}, and F_{y} are elastic modulus and minimum specified yield strength of the used steel. Moreover, in this equation, X should be considered equal to 3, 2.5, 2, and 2, in case of being used for Dₓ 108, D_{y} 110, Dᵣ 112, and Dₘ 114, respectively.

Next, scenarios that do not satisfy compatibility of Dₓ 108, D_{y} 110, Dᵣ 112, and Dₘ 114 (Equations 11-14) are discarded 620. f

Dₘ=Dᵣ (11)

D_{y}>Dᵣ (12)

|Dₓ−D_{y}|≤200 mm (13)

|D_{y}−Dᵣ|≤200 mm (14)

Then, if the distance gap is equal to 50 mm, 200 scenarios, and if 100 mm, 100 scenarios 622 are selected randomly by the algorithm 624. However, if the selected scenario includes the same cross-section set as those in previously selected scenarios 626, the scenario is disregarded, and an alternative scenario is selected 624. This ensures that the scenarios do not concentrate on the same state space. Finally, all the scenarios are stored as the appropriate scenarios 628. Then the algorithm starts the next part (wide field scanning part) 700.

### Wide Field Scanning

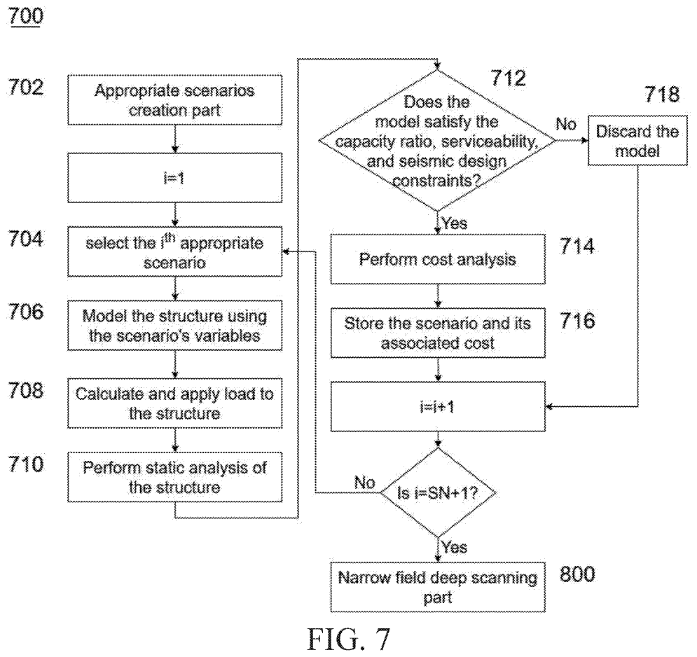

FIG. 7 presents the flowchart of the wide field scanning part 700. This part starts after appropriate scenario creation part 600, then the algorithm one by one selects the scenarios 704, and models the structure using the scenario's variables 706. Subsequently, it calculates and applies the loads 708, performs static analysis 710, and evaluates the capacity ratio, serviceability, and seismic design constraints. If the model satisfies the constraints 712, a cost analysis is performed 714, and the scenario variables along with their associated cost are stored 716. If the model does not satisfy the constraints, it is disregarded 718. Then the algorithm starts the next part (Narrow Field Deep Scanning) 800.

### Narrow Field Deep Scanning

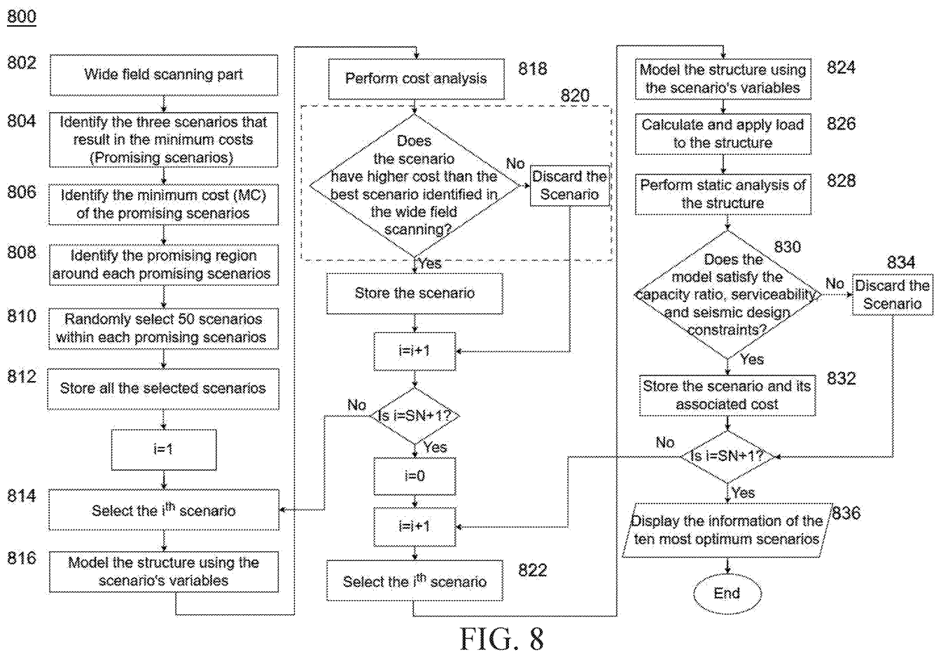

FIG. 8 presents the flowchart of the narrow field deep scanning part 800. This part starts after wide field scanning part 700. In this part, firstly the algorithm reviews the evaluated scenarios and their associated costs to identify the three scenarios that result in the minimum costs (promising scenarios 404) 804. Meanwhile the minimum cost of the promising scenarios is identified 806. Then, the promising regions 408 around each promising scenario 404 are identified 808. A promising region 404 is a region from the previous scenario 410 to the next scenario 412 of each promising scenario 408 found in the wide field scanning step. Then within each promising region 404, 50 scenarios are randomly selected 810. Afterwards, the scenarios are stored 812. Then the algorithm one by one selects the scenarios 814, models the structure using the scenario's variables 816, and performs cost analysis 818. Afterward, the scenarios that have costs higher than the minimum cost identified in the wide field scanning step are discarded 820. From the remaining scenario, like the wide field scanning step, the algorithm one by one selects a scenario 822, models the structure 824, calculates and applies loads 826, performs static analysis 828. Then the capacity ratio, serviceability, and seismic design constraints are checked 830. If the model satisfies the constraints, the scenario variables 136 along with their associated cost are stored 832. If the model does not satisfy the constraints, it is disregarded 834. Finally, ten scenarios 134 leading to the minimum weight are presented 836.

### Numerical Example

### Modeling

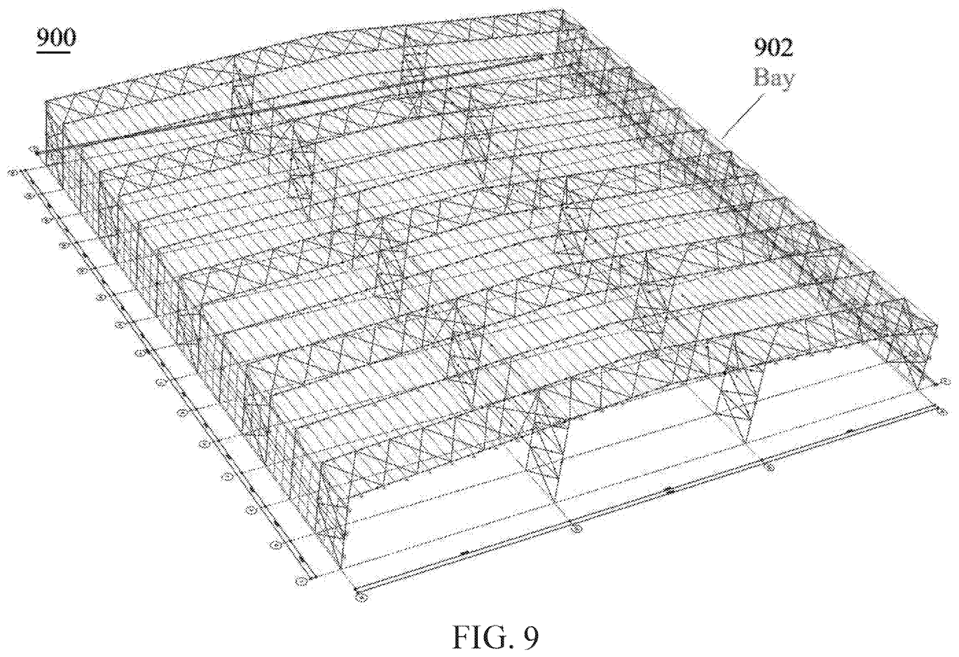

In this section, the optimization methodology is used for the optimal design of a steel frame structure with web-tapered members. A 3D Model of the structure 900 from MKAPEB is shown in FIG. 9. The structure 900 consists of three spans 116, each measuring 26.7 meters (total length=80 meters). It has 14 bays 902, each 6 meters wide. The eave height 118 is 10 meters, and the roof slope is 7.5%. In this structure, the roof purlins are simple @1.325 m c/c, and the roof sheeting is sandwich panel 0.1 kN/m². Moreover, the wall girts are simple @1.6 m c/c, and the side cladding sandwich panel is 0.1 kN/m². The material of primary elements is considered to be S235JR (European Structural Steel).

### Loading

In this example, the load values to be applied to the building 900 are calculated according to ASCE/SEI 7-22 [Minimum Design Loads and Associated Criteria for Buildings and Other Structures, 2022] based on the load parameters presented in Tables 1-4, for snow, wind, thermal, and earthquake loads, respectively.

TABLE 1
The snow load parameters

| | |
|---|---|
| Classification of Building | I |
| Terrain Category | B |
| Snow Surface Type | Unobstructed Slippery Surfaces |
| Exposure Type | Fully Exposed |
| Thermal Condition | Ct = 1 |
| Ground Snow Load | 0.958 kN/m² (20 PSF) |

TABLE 2
The wind load parameters

| Wind Load Code | ASCE-07-22 (Chapter 30) |
|---|---|
| Building Class | II |
| Wind Exposure | B |
| Hurricane Prone | No |
| Wind Speed | 42.5 m/s (95 mph) |
| Enclosure class | Enclosed Buildings |
| Cpi+ | 0.18 |
| Cpi− | −0.18 |

TABLE 3
The thermal load parameters

| | |
|---|---|
| ΔT Summer | 20 °C |
| ΔT Winter | −20 °C |

TABLE 4
The earthquake load parameters

| Seismic Code | ASCE-07-22 |
|---|---|
| Location on map | Latitude: 34.05354; Longitude: −124.24529 |
| | (Los Angeles-California) |
| Site Class | C |
| Site Description | Very dense soil (360 to 760 m/s) |
| | (>250 kPa) and soft rock |
| Importance Factor (I) | II |
| Ss | 1.978 |
| S1 | 0.705 |
| PGA | 0.848 |
| PGV | 0.924 |
| Fa | 1.2 |
| Fv | 1.4 |
| Structural System | C04 Steel ordinary moment frame |
| Reduction factor (R) | 3.5 |
| Overstrength Factor (Ω) | 3 |

Two sets of load combinations are considered in the design and analysis process: design loads and serviceability loads. In this study, the following design load combinations are utilized for the design phase. Here, D, L, Lr, S, R, W, E are dead, live, roof live, snow, rain, wind, and earthquake loads, respectively. Moreover, S_{DS} indicates design earthquake spectral response acceleration at short periods.
1 1.4D
2 1.2D+1.6L+0.5 (Lr or S or R)
3 1.2D+1.6 (Lr or S or R)+ (L or0.8W)
4 1.2 D+1.0 W+L+0.5 (Lr or S or R)
5 (1.2+0.2 S_{DS}) D+E+L+0.2S
6 0.9D+1.0W
7 (0.9+0.2 S_{DS}) D+E

Additionally, the following load combinations are applied as serviceability load combinations.
1 D+L
2 D+0.5S
3 D+0.5L+0.7W

### Structural Analysis

After applying the loads, the structural analysis is conducted using MKAPEB software, a specialized software developed for the analysis and design of single-story steel structures.

### Structural Design Constraints

Several constraints defined by design manuals and specifications must be considered in the optimal design process. These include stability, buckling, strength, maximum vertical displacement, and maximum horizontal displacement constraints. For the structures discussed in this study, these constraints are defined in accordance with AISC-360-16. However, constraints from other specifications can also be incorporated into the optimal design process as needed. Moreover, the design of members subjected to combined forces and torsion is carried out in accordance with Chapter H of AISC 360-16. Additionally, checks for seismic design constraints, story drift limitations, second-order effects, and lateral stability bracing for columns and beams are performed in compliance with AISC 341.

### Optimization Problem and Variables

The optimization problem is defined to minimize the steel usage for the primary members of the structure. The variables in this optimization are considered to be distance parameters 108 110 112 114, side column 102, middle column 104, and rafter 106. The number and descriptions of options of each design variable 136 are presented in the following:
Side Column 102: Built-up H section (Metric)—100 Profile 100
Middle Column 104: Built-up H section (Metric)—50 Profile 100
Rafter 106: Built-up H section (Metric)—50 Profile 100
Distance parameters' 140 gap: 100 mm-5 items for each

Considering the number of items, there are 100×50×50×5×5×5×5=156,250,000 scenarios 134. As can be figured out, considering the existence of numerous scenarios 134, it is impossible for a structural designer to evaluate even 0.01% of the scenarios in a reasonable time to find the optimum scenario. Moreover, because many of the scenarios do not satisfy constraints, or are not feasible to construct, using metaheuristic algorithms to find the best solution is not appropriate.

### Results

As mentioned above, 156,250,000 scenarios 134 existed. In this methodology, however, after applying the filtering and constraints 60,183 scenarios 134 remained. Then, through wide-field scanning and narrow-field deep scanning, the optimal solution is identified within 100 iterations, taking approximately half an hour on a standard home computer.

To verify the methodology, the method is run 5 times.

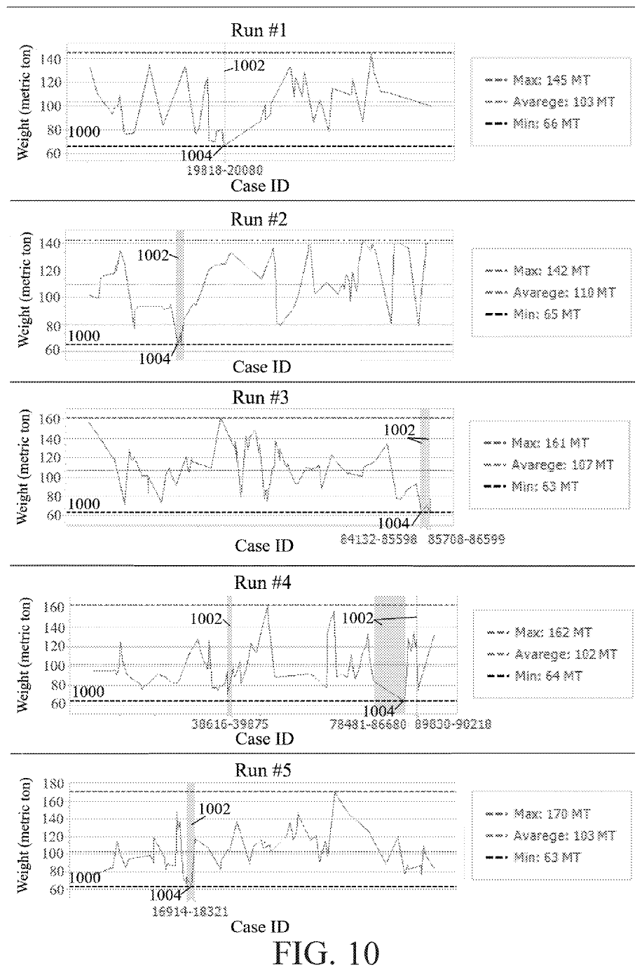

FIG. 10 shows how the algorithm searches the state space 1000 to find promising regions 1002 and optimum scenarios 1004. It can be seen that the optimum solutions exist not in just one region but several regions. The methodology successfully could identify the regions 1002 and find the best results 1004 in all runs.

Table 5 presents the capacity ratio of the 100 solutions that are found in each run of optimization. As can be concluded, on average, almost more than 50% of the investigated solutions are not desired because of having capacity ratios of more than 1 or less than 0.6. It shows that, although all the constraints are considered in the optimization methodology, there is still the chance of reaching undesired solutions (50%). This chance to reach undesired solutions is much more so when the filtering, limitations, and constraints used in this methodology are not considered. Therefore, the chance of a structural designer reaching a solution with a desirable capacity ratio, of less than 1 and more than 0.6 is not 50% but maybe 25%, which means that after 20 tries which take a few days, a designer might reach just 4 acceptable solutions only in terms of capacity ratio. The best of these 4 solutions found by a structural designer may be so far from the real best solution.

TABLE 5
The capacity ratio of the evaluated solutions for each optimization run

| | Capacity ratios (%) | | | | |
|---|---|---|---|---|---|
| Category | Run #1 | Run #2 | Run #3 | Run #4 | Run #5 |
| ratio ≥ 1.0 | 56.3 | 41.0 | 29.1 | 23.8 | 58.6 |
| 0.90 < ratio ≤ 0.99 | 14.3 | 12.3 | 10.9 | 14.9 | 8.6 |
| 0.75 < ratio ≤ 0.90 | 16.8 | 23.8 | 32.7 | 33.7 | 11.1 |
| 0.60 < ratio ≤ 0.75 | 6.7 | 18.0 | 19.1 | 17.8 | 11.7 |
| 0.00 < ratio ≤ 0.60 | 5.9 | 4.9 | 8.2 | 9.9 | 9.9 |

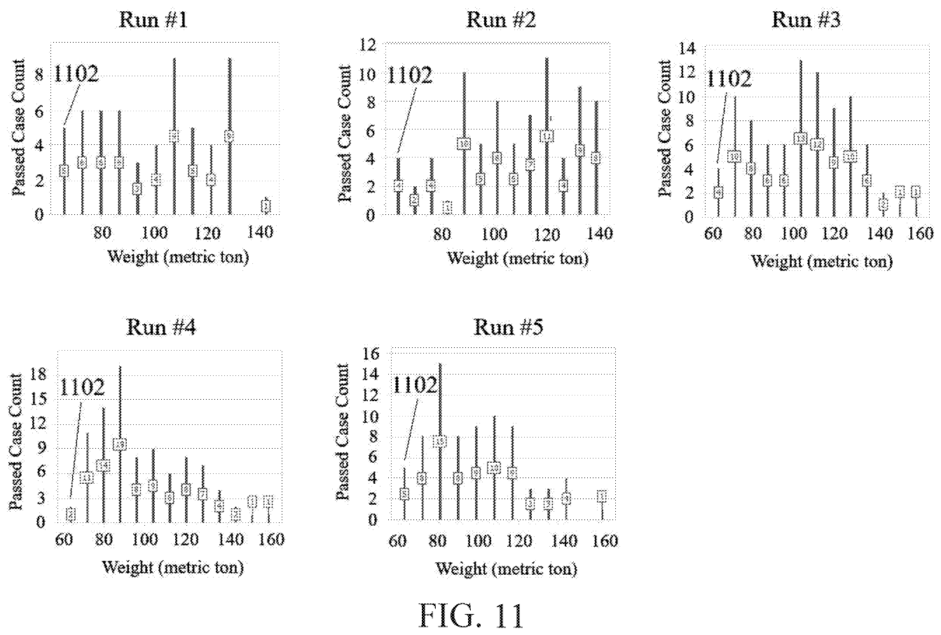

FIG. 11 shows the distribution of the solutions' weight in the state space. As can be seen, among the 100 evaluated solutions, on average 4 of them are within the range of solutions with minimum steel usage 1102. The other solutions have either higher weights or undesired capacity ratios.

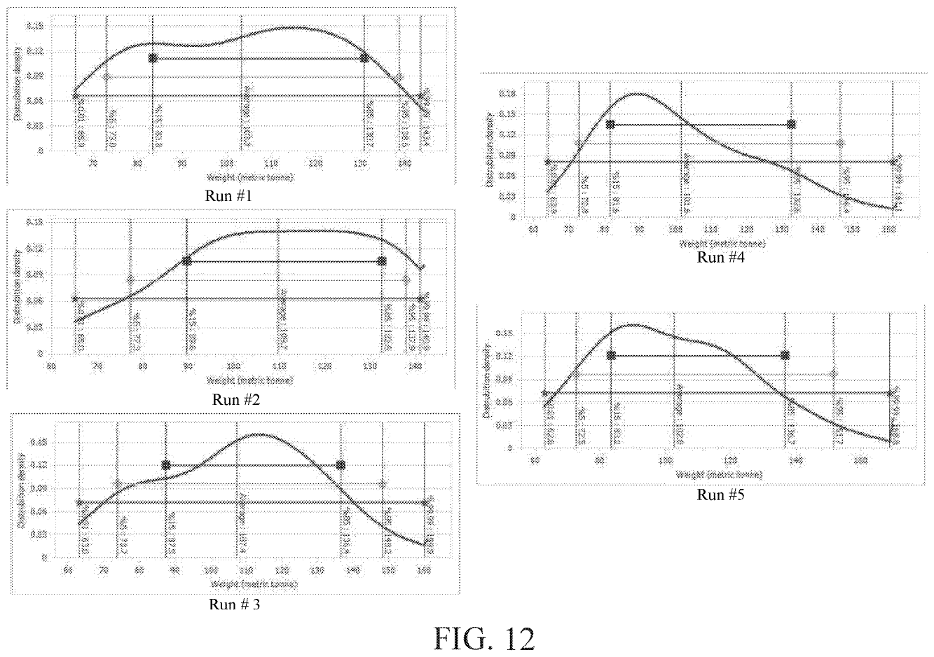

FIG. 12 shows the distribution density of the total weight of the solutions for each run. The weight of the lightest solutions identified in the first to fifth runs are 65.9, 65, 63.0, 63.9, and 62.8 metric tons, respectively.

Moreover, in the state space, there are solutions with weights of more than 168 metric tons, which are more than 2.5 times the lightest solution found by the algorithm.

The statistical analysis shows that even though the probability of reaching a solution with a weight of less than 66 metric tons is almost less than 0.1% the algorithms always could find a solution in this range.

It should be noted that while in the state space, there are solutions with a 100 metric tons difference between their minimum and maximum weights, the minimum and maximum weights of the best solutions found by the algorithm just have almost 3 metric tons difference. It means that the algorithm successfully finds an optimum solution.

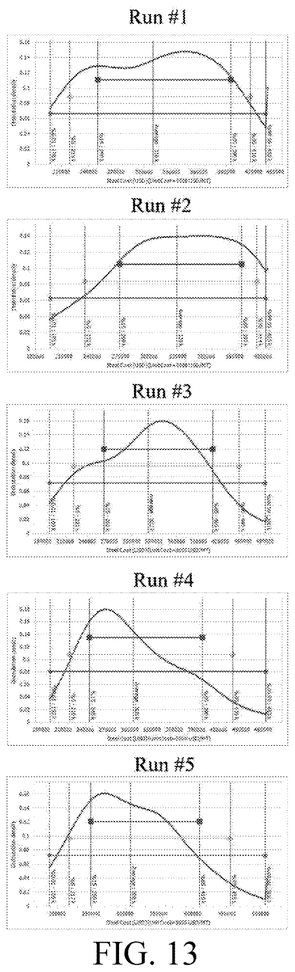

FIG. 13 shows the distribution density of the cost of the steel of primary members of solutions. It is assumed that the cost of the steel is 3000 USD/MT. According to FIG. 13, the minimum, average, and maximum cost of the steel identified in the 5 runs is on average 192000 USD, 315000 USD, and 465000 USD. It means that the ratio between the maximum cost to minimum cost is 2.42, and between the average and minimum cost is 1.64. Assuming a structural designer after several tries can find a desired solution (0.6<capacity ratio<1), and the solution costs the same as the average value (315000 USD), it is still 64% (123000 USD) more expensive.

It should be noted that finding a solution that costs 402000 USD while there are solutions that cost almost 192000 USD is not the designer's fault. First, a designer can't have experience in designing all types of PEB buildings in all regions, in all dimensions, and in all loading situations, to know and guess the range of acceptable and cheap solutions to directly try hundreds of them to find optimum solutions. Moreover, considering that each modeling, statical analysis, design check, and cost analysis, takes on average tens of minutes, after the first modeling and load calculations, and applying load, etc. that takes several hours, an experienced structural designer may try 20 scenarios in a few days, while among the 20 scenarios, several solutions may have desired capacity ratios. The probability of reaching the optimum solutions in this situation is so low. But the algorithm is equipped with a pre-trained model that filters many undesirable solutions just in a second, an auto-appropriate scenarios creation that creates all appropriate and constructible scenarios just in a second, models, applies loads, conducts statical analysis, design checks, and cost analysis all automatically in a few seconds. Therefore, the algorithm can search a hundred solutions to find promising regions in several minutes and evaluates a hundred solutions within the promising regions to find the best solution again in several minutes, all with a standard computer.

The advantage of using the algorithm for designing this model is not limited to finding a solution that requires an average of 70 metric tonnes (50%) less steel or requires 210000 USD less cost for the primary members of the structure but decreasing 132 tons less CO₂ emissions from the production of the required steel (Assuming each 1-ton steel production emits 1.85 tons CO₂).

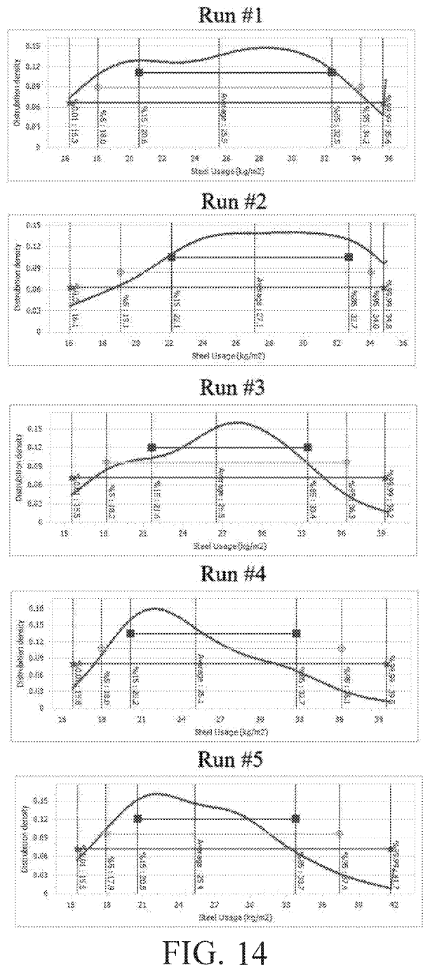

FIG. 14 presents the steel usage per meter square for primary members of different solutions found by the algorithm. As shown in the figure, for each square meter, an average of 25-kilogram steel is needed, which leads to almost 46 kg CO₂ emission, while the algorithm can find a solution that requires 16-kilogram steel for each square meter which leads to 30 kg CO₂ emission. In other words, by using this method for each meter square of the structure 16 kg less CO₂ is emitted compared to the average. It should be noted that considering the worst solutions (on average 38 kg/m² steel usage), by using this method 40 kg less CO₂ is emitted for primary members of each square meter of the structure.

In summary, the results of the study demonstrate the methodology's capability to identify optimal solutions across a diverse state space, achieving significant reductions in steel usage, cost, and carbon emissions. Specifically, in a numerical study, the algorithm consistently identifies solutions that compared to traditional methods use at least 50% less steel, translating into substantial cost savings (approximately $210,000) and a reduction of 132 tons in CO₂ emissions for the primary members of an analyzed structure.

### CONCLUSION

In summary, embodiments of the invention provide a computer-implemented method for the optimal design of PEB structures. In this method, a user may define the structural properties, such as span length, column height, bay width, etc., and loading properties such as snow, seismic, and wind loading parameters. Then based on the structural and loading properties by using a trained model, and considering several types of constraints, the algorithm creates all appropriate scenarios for the structure. Then by a systematic search, the algorithm selects a scenario, models the structure based on the scenario, automatically calculates and applies the loads on the primary members, conducts structural analysis, checks the regulations' constraints, and performs cost analysis to find the most optimum scenario among a wide range of scenarios in a reasonable time. To evaluate the efficiency of the algorithm in finding the optimal design of the primary members of a PEB structure, a numerical study is conducted. The algorithms then run five times. According to the results, while the weight of the primary member of the structure can vary almost from 63 tons to more than 134 tons, the algorithm in all five runs found scenarios with weights in the range of 63 to 66 tons. It is while, according to statistical analysis, the probability of reaching these values in the state space is less than 0.1%. Moreover, the whole optimization process, from defining the structural properties to finding the optimum scenarios with a standard computer, took less than 30 minutes. In traditional designing methodology using common structural analysis software, however, it takes a full day for a structural designer to model the structure, calculate applied loads to each structural element, conduct structural analysis, and check all design constraints and limitations to reach acceptable designs. However, the weight of the designs may still be much higher than the most optimum design. By conducting the whole modeling, loading, statistical analysis, constraints checking, and cost analyzing process tens of times, which takes more than a full week, a structural designer maybe can reach a design similar to optimum designs. However, this much energy and time is not always available. This algorithm helps structural designers to reach optimum designs not in a week but in an hour, which would be beneficial, especially in tenders. It should be mentioned that it is not beneficial just for companies to win tenders because of being able to offer the most optimum designs in a shorter time, and it is not beneficial just for investors to construct their projects with a lower price due to a reduction in the amount of steel usage and subsequently labor works, shipping, etc. but is beneficial for everyone because the reduction in steel usage leads to a reduction in CO₂ emissions and subsequently to ecosystems protection, energy security enhancement, and slowing down climate change.

### REFERENCES

[Arzani 2019] Arzani, H., Kaveh, A., & Kamalinejad, M. (2019). Optimal design of pitched roof rigid frames with non-prismatic members using quantum evolutionary algorithm. Periodica Polytechnica Civil Engineering, 63(2), 593-607. https://doi.org/10.3311/PPci.14091
[Babaei 2022] Babaei, M., & Moharrami, H. (2022). Geometry and sizing optimization of steel gable frames with tapered members. Structures, 42, 575-585. https://doi.org/10.1016/J.ISTRUC.2022.05.094
[Balamuralikrishnan 2019] Balamuralikrishnan, R., & Mohammedali, I. S. (2019). Comparative Study on Two Storey Car Showroom Using Pre-engineered Building (PEB) Concept Based on British Standards and Euro Code. Civil Engineering Journal (Iran), 5(4), 881-891. https://doi.org/10.28991/cej-2019-03091296
[Caldeira 2019] Caldeira, R. H., & Gnanavelbabu, A. (2019). Solving the flexible job shop scheduling problem using an improved Jaya algorithm. Computers & Industrial Engineering, 137, 106064. https://doi.org/10.1016/j.cie.2019.106064
[Dordaie 2018] Dordaie, N., & Navimipour, N. J. (2018). A hybrid particle swarm optimization and hill climbing algorithm for task scheduling in the cloud environments. ICT Express, 4(4), 199-202. https://doi.org/10.1016/J.ICTE.2017.08.001
[Escamilla-Serna 2022] Escamilla-Serna, N. J., Seck-Tuoh-Mora, J. C., Medina-Marin, J., Barragan-Vite, I., & Corona-Armenta, J. R. (2022). A Hybrid Search Using Genetic Algorithms and Random-Restart Hill-Climbing for Flexible Job Shop Scheduling Instances with High Flexibility. Applied Sciences 2022, Vol. 12, Page 8050, 12(16), 8050. https://doi.org/10.3390/APP 12142,050
[Gilbile 2020] Gilbile, M. J., & Mane, S. S. (2020). A Review on Comparative Study on the Structural Analysis and Design of Pre-Engineered Building [PEB] with Conventional Steel Building [CSB]. International Journal of Engineering Research & Technology (IJERT), 9(9), 56-58. www.ijert.org
[Kato 2018] Kato, E. R. R., Aranha, G. D. de A., & Tsunaki, R. H. (2018). A new approach to solve the flexible job shop problem based on a hybrid particle swarm optimization and Random-Restart Hill Climbing. Computers & Industrial Engineering, 125, 178-189. https://doi.org/10.1016/J.CIE.2018.08.022
[Kaveh 2021] Kaveh, A., Dastjerdi, M. I. K., Zaerreza, A., & Hosseini, S. M. (2021). Discrete Optimum Design of Planar Steel Curved Roof and Pitched Roof Portal Frames Using Metaheuristic Algorithms. Periodica Polytechnica Civil Engineering, 65(4), 1092-1113. https://doi.org/10.3311/PPci.18425
[Kaveh 2019] Kaveh, A., & Ghafari, M. H. (2019). Geometry and Sizing Optimization of Steel Pitched Roof Frames with Tapered Members Using Nine Metaheuristics. Iranian Journal of Science and Technology-Transactions of Civil Engineering, 43(1), 1-8. https://doi.org/10.1007/s40996-018-0132-1
[Kaveh 2019] Kaveh, A., Kabir, M. Z., & Bohlool, M. (2019). Optimal design of multi-span pitched roof frames with tapered members. Periodica Polytechnica Civil Engineering, 63(1), 77-86. https://doi.org/10.3311/PPci.13107
[Lee 2015] Lee, S. H., Kim, Y. H., & Choi, S. M. (2015). Ultimate strength of long-span buildings with P.E.B (Pre-Engineered Building) system. Steel and Composite Structures, 19(6), 1483-1499. https://doi.org/10.12989/scs.2015.19.6.1483
[Lim 2006] Lim, A., Rodrigues, B., & Zhang, X. (2006). A simulated annealing and hill-climbing algorithm for the traveling tournament problem. European Journal of Operational Research, 174(3), 1459-1478. https://doi.org/10.1016/J.EJOR.2005.02.065
[Liu 2018] Liu, H. D., Lin, C. H., Pai, K. J., & Lin, Y. L. (2018). A novel photovoltaic system control strategies for improving hill climbing algorithm efficiencies in consideration of radian and load effect. Energy Conversion and Management, 165, 815-826. https://doi.org/10.1016/J.ENCONMAN.2018.03.081
[Maria Subashini 2015] Maria Subashini, L., & Valentina, S. (2015). comparative Study of Preengineered and Conventional Industrial Building. Indian Journal of Science and Technology, 8(32). https://doi.org/10.17485/ijst/2015/v8132/89102
[Milan Girishkumar 2022] Milan Girishkumar, S., Rajeshkumar Suthar, A., & Sankhla, M. (2022). Structural Analysis of (PEB) Pre-Engineered Building Using Different Types of Bracing on Lateral Load. International Journal of Advances in Engineering and Management (IJAEM), 4(6). https://doi.org/10.35629/5252-04060416
[Minimum Design Loads and Associated Criteria for Buildings and Other Structures. 2022] Minimum Design Loads and Associated Criteria for Buildings and Other Structures. (2022). American Society of Civil Engineers.
[Pappala 2023] Pappala, S. (2023). Hill-Climbing Search Artificial Intelligence. https://www.researchgate.net/publication/378679524
[Qin 2019] Qin, H., Fan, P., Tang, H., Huang, P., Fang, B., & Pan, S. (2019). An effective hybrid discrete grey wolf optimizer for the casting production scheduling problem with multi-objective and multi-constraint. Computers & Industrial Engineering, 130, 458-476. https://doi.org/10.1016/j.cie.2018.12.061
[Rao 2014] Rao, K. M. N., & Vishwanath, K. N. (2014). Design Optimisation of an Industrial Structure from Steel Frame to Pre-Engineered Building. International Journal of Research in Advent Technology, 2(9).
[Russell 2002] Russell, S., & Norvig, P. (2002). Artificial Intelligence: a Modern Approach (Second). Pearson.
[Sagavekar 2021] Sagavekar, A., & Khurd, V. (2021). Optimization of Pre-Engineered Building Structures. International Research Journal of Engineering and Technology. www.irjet.net
[Salama 2023] Salama, A., Atif, A., Eraky, A., & Samir, R. (2023). Optimal design of steel gable frames with tapered members using Enhanced Crystal Structure Algorithm (ECryStAl). Structures, 50, 1742-1751. https://doi.org/10.1016/J.ISTRUC.2023.03.019
[Sathiyaraj 2022] Sathiyaraj, C., Ramachandran, M., Amudha, M., & Kurinjimalar, R. (2022). A Review on Hill Climbing Optimization Methodology. Recent Trends in Management and Commerce, 3(1), 1-7. https://doi.org/10.46632/rmc/3/1/1
[Selvam 2019] Selvam, P. P., & Narayanan, R. (2019). Random Restart Local Search Optimization technique for sustainable energy-generating induction machine. Computers and Electrical Engineering, 73, 268-278. https://doi.org/10.1016/j.compeleceng.2018.11.023
[Sunanda 2022] Sunanda, K., Shaik, R. A., Sushmapriya, K., Bhagyalakshmi, V., Manaswini, T., & Kaveri, B. (2022). Analysis and Design of Pre-Engineering Building. In International Journal of Research in Engineering, IT and Social Sciences (Vol. 12). http://indusedu.org
[Syed Shujat 2018] Syed Shujat, Q., & Desai, R. (2018). Comparative Study of Design of Industrial Warehouse Using CSB, PEB and Tubular Sections. Journal of Engineering Research and Application Www.Ijera.Com, 8, 53-57. https://doi.org/10.9790/9622-0805015357
[Tran 2022] Tran, V. Q. (2022). Hybrid gradient boosting with meta-heuristic algorithms prediction of unconfined compressive strength of stabilized soil based on initial soil properties, mix design and effective compaction. Journal of Cleaner Production, 355, 131423. https://doi.org/10.1016/J.JCLEPRO.2022.131423

1. A computer-implemented method for the optimal design of pre-engineered steel building structures, comprising:
creating an appropriate scenario; and
scanning a field.

2. The computer-implemented method of claim 1, wherein creating the appropriate scenario comprises:
building a section dataset;
filter a cross-section; and
creating the scenario.

3. The computer-implemented method of claim 2, wherein building the section dataset comprises:
importing smart cross-sections; and
importing user-defined cross-sections.

4. The computer-implemented method of claim 2, wherein filtering the cross-section comprises:
exporting structural properties and load-related properties to a server;
importing the minimum and maximum of ranges of flange width, web height, and flange thickness of columns and rafters from web-service; and
importing the cross-sections within the ranges from the cross-section dataset.

5. The computer-implemented method of claim 2, wherein creating the scenario comprises:
discarding cross sections that do not satisfy size constraints;
generating all possible combinations of columns and rafter sections;
discarding the cross-section combinations that do not satisfy section compatibility;
importing user-defined values for a gap between the items of variables of distance set;
generating sets for variables of distance set; and
generating all possible scenarios.

6. The computer-implemented method of claim 1, wherein scanning the field comprises:
selecting a scenario;
modeling PEB structures;
automatically assigning loads;
performing static analysis;
checking constraints of the regulations;
performing cost analysis; and
presenting the optimization results.

7. The computer-implemented method of claim 6, wherein selecting the scenario comprises:
systematic searching and selecting of a scenario from a range of pre-provided scenarios.

8. The computer-implemented method of claim 6, wherein modeling the PEB structures comprises:
importing a type of PEB structure;
importing structural properties including span length, column height, bay width, mid-column presence, base support type (fixed or pinned), side-column type (straight or tapered); and
creating a model of the PEB structure considering the structural properties and type of structure.

9. The computer-implemented method of claim 6, wherein the automatically assigning loads comprises:
importing snow, wind load-related properties;
importing seismic load-related properties;
automatically calculating the load applied to each structural element; and
automatically applying load to each structural element.

10. The computer-implemented method of claim 6, wherein the performing structural analysis comprises:
statically analyzing the structure; and
calculating axial forces, shear forces, bending moments.

11. The computer-implemented method of claim 6, wherein the checking of the regulations' constraints comprises:
checking capacity ratio;
checking serviceability constraints; and
checking seismic design constraints.

12. The computer-implemented method of claim 6, wherein the cost analysis comprises:
importing the cost of steel per kilogram;
calculating a steel amount of primary members; and
a total steel weight of the structure, steel weight of structure per meter square, cost of total steel used for primary elements of the structure.

13. The computer-implemented method of claim 6, wherein the presenting the optimization results comprises:
presenting optimal variables, capacity ratios, and total weight for each best solutions found;
illustrating searched scenarios in a state space;
illustrating capacity ratios of the searched scenarios;
illustrating a distribution of the weight of passed solutions in the state space;
Illustrating a distribution density of the total weight of primary members of all solutions;
Illustrating a distribution density of a total cost of the primary members of all solutions; and
Illustrating a distribution density of the total weight per meter square for the primary members of all solutions.
